(19) United States
(12) Patent Application Publication
(10) Pub. No.: US 2006/0087031 A1
(43) Pub. Date: Apr. 27, 2006

(54) Assembly and method

(75) Inventors: Ian Andrew Gardner, Cambridge (GB); Robert Charles Wilson, Bucks (GB)

Correspondence Address: SUGHRUE MION, PLLC, 2100 PENNSYLVANIA AVENUE, N.W., SUITE 800, WASHINGTON, DC, 20037, US

(73) Assignee: FUJIFILM ELECTRONIC IMAGING LTD., Hertfordshire (GB)

(21) Appl. No.: 10/973,144

(22) Filed: Oct. 25, 2004

(51) Int. Cl. H01L 29/08; H01L 21/44

(52) U.S. Cl. 257/734; 257/750; 438/652

(57) ABSTRACT

An assembly comprises a substrate, such as a printed circuit board, with an electrically insulating layer provided thereon. The electrically insulating layer defines at least one opening, said opening being formed in a shape of an indicium relating to an aspect of the assembly.

### FIELD OF THE INVENTION

The invention relates to an assembly and a method of manufacturing such an assembly.

### DESCRIPTION OF THE PRIOR ART

Printed circuit boards are typically provided with an electrically insulating layer such as a solder mask to insulate the circuit and components both electrically and from the environment. The solder mask layer also prevents solder from a later soldering process contacting the printed circuit board components or circuit. In some cases, as described for example in EP-A-0997935 and US-A-2001/107768, the solder mask may include one or more openings to allow connection to circuit components and/or provide vents.

In order to identify the printed circuit board or one or more components on the circuit board, it is conventional to screen or inkjet print one or more legends onto the surface of the solder mask.

A number of problems arise with this known process. For example, the printed legend is subject to erasure due to poor adhesion with the solder mask material, legends often have poor image quality, and the time required to fabricate the printed circuit board assembly increases as a result of the need for the printing step.

### SUMMARY OF THE INVENTION

In accordance with a first aspect of the present invention, an assembly comprises a substrate with an electrically insulating layer provided thereon, the electrically insulating layer defining at least one opening, said opening being formed in a shape of an indicium relating to an aspect of the assembly.

In accordance with a second aspect of the present invention, a method of manufacturing an assembly comprises providing an electrically insulating layer over a substrate; and forming at least one opening in the electrically insulating layer, said opening being formed in the shape of an indicium relating to an aspect of the assembly.

With this invention, we utilize the electrically insulating layer itself to provide the indicium or, in many cases, plurality of indica, for example defining a legend. This leads to a number of advantages over the known assemblies and methods described above.

For example, it enables improved registration to be achieved between the electrically insulating layer and the indicum or indicia which in turn enables the process to be used accurately with substrates such as printed circuit boards, for example High Density Interconnect circuit boards, having many components with which the indicia or legends need to be closely associated.

By omitting the surface printing of a legend, the problems of adhesion are eliminated and this method also leads to improved image quality. The electrically insulating layer provides good mechanical properties and, of course, the elimination of a separate surface printing step reduces the manufacturing time required.

As already explained, in a simple case, a single opening defining a single indicium could be provided but in most cases a plurality of openings are provided which together define a legend.

These openings could be blind in the sense that they extend only partially through the electrically insulating layer or may extend fully through the insulating layer. In the latter case, it is usually preferable to fill the opening(s) fully or partially with a further insulating material. It is particularly convenient if the openings are at least partially filled with a material having a colour contrasting with that of the electrically insulating layer so as to increase the visibility of the indicia. This contrasting colour material may fully fill an opening or, in the case of an opening which extends completely through the electrically insulating layer, this opening could be partially filled with an electrically insulating material followed by a material of a contrasting colour (which need not be electrically insulating).

The indicia could take any conventional shape known in the art but typically comprise alphanumeric characters.

The or each opening could be fully formed during the step of providing the electrically insulating layer or the electrically insulating layer could be provided first followed by the formation of the or each opening.

Although the invention is particularly suited for use with printed circuit boards, it could also be used for creating identification marking within insulating layers for other electronic devices e.g. protective coatings for electronic packaging, flat panels for displays etc.

### BRIEF DESCRIPTION OF THE DRAWINGS

Some examples of assemblies and methods according to the invention will now be described with reference to the accompanying drawings, in which:

FIG. 1 is a schematic plan view of an assembly;

FIG. 2 is a schematic section taken on the line A-A in FIG. 1;

FIG. 3 is a flow diagram illustrating various different methods according to the invention;

FIG. 4 is a plan of part of a second assembly according to the invention;

FIG. 5 is a view similar to FIG. 4 but illustrating a modified opening; and,

FIG. 6 is a section on the line B-B in FIG. 4.

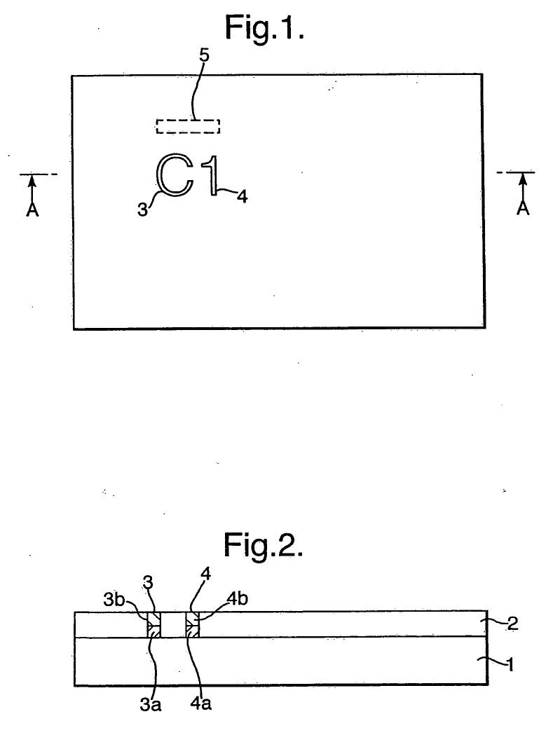

The assembly shown in FIGS. 1 and 2 comprises a conventional printed circuit board (PCB) 1 carrying electrical circuits and electrical components (one shown schematically at 5) in the usual way. The surface of the PCB 1 is provided with a solder mask layer 2, again of conventional form, but which has been provided with a pair of openings 3,4 defining the letter “C” and the numeral “1”. As illustrated schematically in FIG. 1, this legend C1 is provided adjacent an underlying component 5 to which it relates.

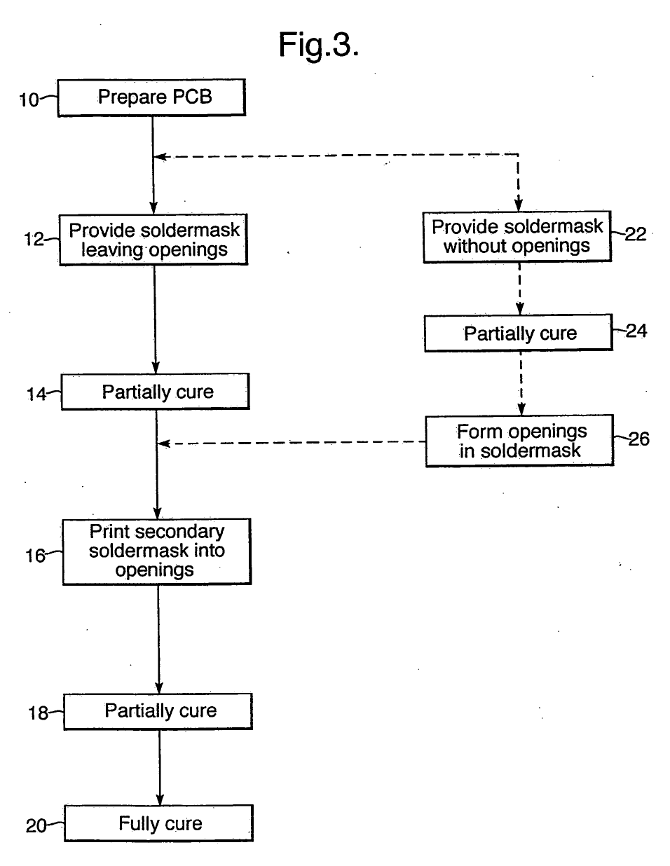

There are several different methods by which the structure shown in FIGS. 1 and 2 can be fabricated. Some examples of this are set out in the flow diagram of FIG. 3.

In an initial step 10, the PCB is prepared in the usual way by providing it with electrical components and circuits. The material also has to be surface cleaned so as to provide good adhesion to the solder mask layer 2.

In step 12, the solder mask layer 2 is provided on the surface of the PCB 1. This can be achieved using conventional photolithography or LDI processing of the (primary) solder mask material or alternatively the material could be printed, for example inkjet or screen printed, onto the surface of the PCB 1. In either case, in this example, the solder mask layer 2 is provided with predefined openings 3,4 which, as can be seen in FIG. 2, extend fully through the thickness of the layer 2.

The structure at this stage is then partially cured, for example using UV, IR or thermal curing (step 14) so that the layer 2 is at least tacked onto the surface of the PCB 1.

A secondary solder mask material is then inkjet or otherwise printed into the openings 3,4 (step 16). This secondary solder mask material is chosen to have a colour which contrasts with the colour of the primary solder mask material of the layer 2. These materials may be chosen to have colours such as green, red, blue, white etc.

The secondary solder mask material is then partially cured (step 18) and this allows the partially cured assembly to be transported to another location for final, full curing in a step 20. The partial cure of secondary material may also affect the level of curing of the primary material to some extent, but should not be of importance, for example it is possible to partially cure using UV and then full cure both primary and secondary materials at same time using a thermal bake. This will help to achieve good, continuous layer properties.

It will be appreciated that several variations of this method could be used. For example, the primary material could be fully cured in step 14 rather than partially cured while the partial cure step 18 could be omitted.

A particular advantage of inkjet or otherwise controlled printing of the secondary solder mask material in step 16 is that the quantity of that material can be closely controlled. It is therefore possible to precalculate the volume of material needed to fill each opening 3,4 and then to supply that volume only in step 16. This ensures that the resultant assembly has a planar finish with little if any legend marking thickness above the solder mask 2 surface. This makes the assembly less prone to mechanical damage.

It will be appreciated that since the openings 3,4 extend fully through the solder mask layer 2, the material which is supplied first to the openings 3,4 must also be electrically insulating. However, although in the example just described, this material is used fully to fill the openings 3,4, it is possible to use an electrically insulating material which only partially fills the openings 3,4 as shown at 3a,4a in FIG. 2 and then to use a different material 3b,4b to fill the remainder of the openings 3,4. The advantage of this is that it allows more flexibility in the choice of visible colours since these are not restricted to those available with electrically insulating materials.

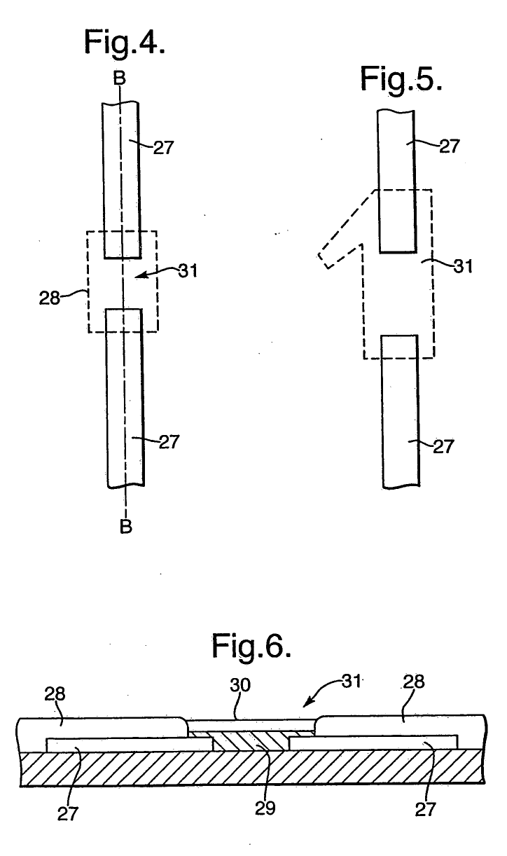

In an alternative method (FIGS. 4 to 6), the opening 31 in soldermask layer 28 could be at least partially filled with a functional material 29 for the production of embedded components such as resistors, capacitors, inductors, light emitting materials (e.g. OLEDs). This can be achieved by registration of the opening 21 above electrical contacts 27 (e.g. copper track or pads). The functional material 29 is then firstly deposited into the opening 31 and may be optionally covered by further layers or a secondary soldermask layer 30 (with any of the previously defined properties). The opening 31 may take any shape including alphanumeric (see FIG. 5) if required to improve density of components and marking.

In the methods described so far, the primary solder mask is provided with the required openings already defined. In an alternative approach, instead of performing steps 12 and 14, a contiguous primary solder mask layer could be provided (step 22) which is then partially cured (step 24) and then the openings are formed in that partially cured layer (step 26). Step 26 could be carried out using laser drilling or laser ablation for example which typically enables higher accuracy to be achieved.

It will be appreciated that although a single legend and component have been shown in FIG. 1, in practice there may be several legends present, each indicating an adjacent electrical component on the underlying PCB or possibly also providing a definition of the function of the PCB.

We claim:

1. An assembly comprising a substrate with an electrically insulating layer provided thereon, the electrically insulating layer defining at least one opening, said opening being formed in a shape of an indicium relating to an aspect of the assembly.

2. An assembly according to claim 1, wherein a plurality of openings are defined by the electrically insulating layer, the openings defining indicia forming a legend.

3. An assembly according to claim 2, wherein the substrate supports an electrical component, the legend defining information relating to the electrical component.

4. An assembly according to claim 3, wherein the legend is located adjacent the electrical component.

5. An assembly according to claim 1, wherein the shape of the indicium defines an alphanumeric character.

6. An assembly according to claim 5, wherein the substrate supports an electrical component, the indicium being related to the electrical component.

7. An assembly according to claim 6, wherein the indicium is located adjacent the electrical component.

8. An assembly according to claim 1, wherein said at least one opening is filled with a material having a colour contrasting with the colour of the electrically insulating layer.

9. An assembly according to claim 8, wherein said material is electrically insulating.

10. An assembly according to claim 9, wherein the at least one opening extends through the electrically insulating layer to the substrate.

11. An assembly according to claim 8, wherein said material comprises a printing ink.

12. An assembly according to claim 11, wherein the material comprises an ink jet printing ink.

13. An assembly according to claim 1, wherein the electrically insulating layer comprises a solder resist.

14. An assembly according to claim 1, wherein the opening is at least partially filled with a functional material in electrical communication with an electrical component or contact on the substrate.

15. An assembly according to claim 1, wherein the substrate comprises a printed circuit board.

16. A method of manufacturing an assembly, the method comprising providing an electrically insulating layer over a substrate; and forming at least one opening in the electrically insulating layer, said opening being formed in the shape of an indicium relating to an aspect of the assembly.

17. A method according to claim 16, wherein the at least one opening is formed during the step of providing the electrically insulating layer.

18. A method according to claim 16, wherein the at least one opening is formed after the step of providing the electrically insulating layer.

19. A method according to claim 16, further comprising filling the at least one opening with a material having a colour contrasting with the colour of the electrically insulating layer.

20. A method according to claim 19, wherein the said material is electrically insulating.

21. A method according to claim 20, wherein the at least one opening extends through the electrically insulating layer to the substrate.

22. A method according to claim 19, wherein the quantity of the said material delivered to the at least one opening is calculated in advance such that the said quantity substantially exactly fills the opening.

23. A method according to claim 19, wherein said material comprises a printing ink.

24. A method according to claim 23, wherein said material comprises an ink jet printing ink.

25. A method according to claim 16, further comprising at least partially curing the electrically insulating layer.

26. A method according to claim 16, further comprising partially curing the electrically insulating layer after it has been provided on the substrate, filling the or each opening with a material having a colour contrasting with the colour of the electrically insulating layer, and thereafter fully curing the electrically insulating layer and the material.

27. A method according to claim 16, wherein the shape of the indicium defines an alphanumeric character.

28. A method according to claim 16, wherein a plurality of openings are defined by the electrically insulating layer, the openings defining indicia forming a legend.

29. An method according to claim 28, wherein the substrate supports an electrical component, the legend defining information relating to the electrical component.

30. A method according to claim 29, wherein the legend is located adjacent the electrical component.

31. A method according to claim 27, wherein the substrate supports an electrical component, the indicium being related to the electrical component.

32. A method according to claim 31, wherein the indicium is located adjacent the electrical component.

33. A method according to claim 16, wherein the electrically insulating layer is a solder resist.

34. A method according to claim 16, wherein the substrate comprises a printed circuit board.

35. A method according to claim 16, wherein the opening is at least partially filled with a functional material in electrical communication with an electrical component or contact on the substrate.
